(19) United States
(12) Patent Application Publication
(10) Pub. No.: US 2019/0333734 A1
(43) Pub. Date: Oct. 31, 2019

(54) CHARGED PARTICLE BEAM WRITING APPARATUS AND CHARGED PARTICLE BEAM WRITING METHOD

(71) Applicant: NuFlare Technology, Inc., Yokohama-shi (JP)

(72) Inventor: Hideki Matsui, Yokohama-shi (JP)

(73) Assignee: NuFlare Technology, Inc., Yokohama-shi (JP)

(21) Appl. No.: 16/380,244

(22) Filed: Apr. 10, 2019

(30) Foreign Application Priority Data
Apr. 25, 2018 (JP) 2018-084213

(51) Int. Cl. H01J 37/317; H01J 37/304

(52) U.S. Cl. CPC H01J 37/3174; H01J 2237/31793; H01J 2237/30461; H01J 37/304

(57) ABSTRACT

In one embodiment, a charged particle beam writing apparatus includes a storage storing coefficients of a calculation formula for calculating a correction amount of a beam emission position according to an atmospheric pressure, a correction amount calculator calculating a correction amount of the beam emission position from a measured value of an atmospheric pressure sensor and the calculation formula using the coefficients, a writer writing a pattern on a substrate using a charged particle beam with the beam emission position adjusted based on shot data and the correction amount, a correction residual calculator calculating a correction residual for the emission position of the charged particle beam using a result of detection by a detector, and an updater updating the coefficients, when there is correlation between change in the correction residual and change in the atmospheric pressure.

### CROSS REFERENCE TO RELATED APPLICATION

This application is based upon and claims benefit of priority from the Japanese Patent Application No. 2018-84213, filed on Apr. 25, 2018, the entire contents of which are incorporated herein by reference.

### FIELD

The present invention relates to a charged particle beam writing apparatus and a charged particle beam writing method.

### BACKGROUND

With an increase in the packing density of LSIs, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

It is known that a path of an electron beam is changed due to disturbance such as an atmospheric pressure change. Conventionally, a relational expression between atmospheric pressure change and beam emission position variation is determined by prior measurement, and writing is performed while correcting the emission position using the relational expression.

The column (lens barrel) of the writing apparatus is formed by stacking cylindrical blocks in a plurality of stages. The state of a joint portion of each block is varied by the atmospheric pressure and is not stable. Thus, even when the emission position is corrected using the relational expression determined by prior measurement, correction residual occurs, and it is difficult to improve the writing accuracy.

### BRIEF DESCRIPTION OF THE DRAWINGS

FIG. 1 is a schematic view of an electron beam writing apparatus according to an embodiment of the present invention.

FIG. 2 is a perspective view of a first shaping aperture and a second shaping aperture.

FIG. 3 is a flowchart explaining a method of updating a correction coefficient according to the embodiment.

### DETAILED DESCRIPTION

In one embodiment, a charged particle beam writing apparatus includes a shot data generator generating shot data from writing data, the shot data including a position and a beam emission time for each shot, a storage storing coefficients of a calculation formula for calculating a correction amount of a beam emission position according to an atmospheric pressure, an atmospheric pressure sensor measuring the atmospheric pressure, a correction amount calculator calculating a correction amount of the beam emission position from a measured value of the atmospheric pressure sensor and the calculation formula using the coefficients, a writer writing a pattern on a substrate using a charged particle beam with the beam emission position adjusted based on the shot data and the correction amount, a detector scanning a mark, provided on a stage on which the substrate is placed, with the charged particle beam, and detecting a reflection electron reflected from the mark, a correction residual calculator calculating a correction residual for the emission position of the charged particle beam using a result of detection by the detector, and an updater updating the coefficients, when there is correlation between change in the correction residual and change in the atmospheric pressure.

Hereinafter, an embodiment of the present invention will be described based on the drawings.

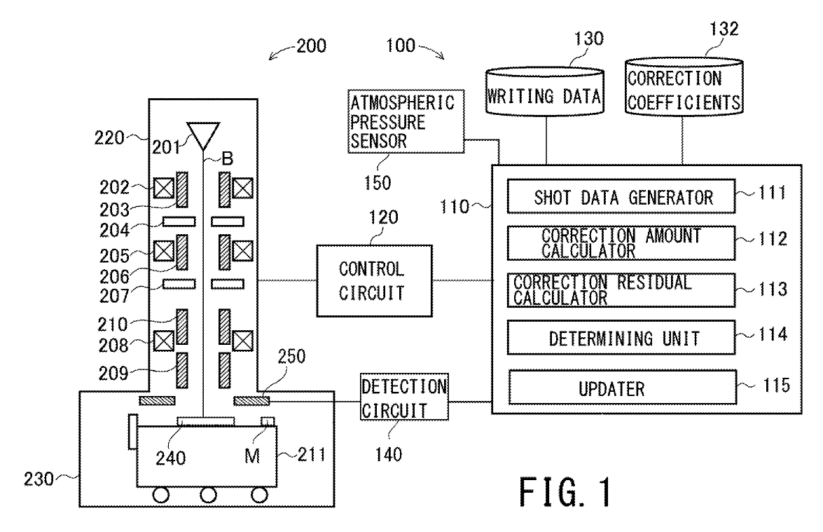

FIG. 1 is a schematic view of an electron beam writing apparatus according to an embodiment of the present invention. The electron beam writing apparatus illustrated in FIG. 1 is a variable shape type writing apparatus including a controller 100 and a writing unit 200 (a writer).

The writing unit 200 includes a column 220 (an electron lens barrel) and a writing chamber 230. In the column 220, an electron gun 201, an illumination lens 202, a blanker 203, a first shaping aperture 204, a projection lens 205, a shaping deflector 206, a second shaping aperture 207, an objective lens 208, a main deflector 209, a sub-deflector 210, and a detector 250 are disposed.

A XY stage 211 is disposed in the writing chamber 230. A substrate 240, which is a writing target, is placed on the XY stage 211. A mark M is disposed on the XY stage 211 at a position different from the position where the substrate 240 is placed. The mark M is, for example, a cross-shaped mark made of metal.

When an electron beam B discharged from the electron gun 201 (discharger) provided in the column 220 passes through in the blanker (planking deflector) 203, it is switchable by the blanker 203 whether or not the electron beam is emitted to the substrate.

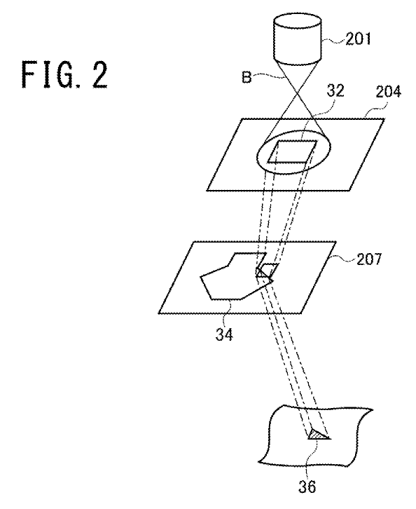

The electron beam B is emitted to whole of the first shaping aperture 204 having a rectangular opening 32 (see FIG. 2) via the illumination lens 202. The electron beam B is shaped into a rectangular form by passing through the opening 32 of the first shaping aperture 204.

The electron beam B with a first aperture image, which has passed through the first shaping aperture 204, is projected on the second shaping aperture 207 having a variable shaped opening 34 (see FIG. 2) by the projection lens 205. At this point, the first aperture image projected on the second shaping aperture 207 is deflection-controlled by the deflector 206, and the shape and size of an electron beam which passes through the variable shaped opening 34 can be changed (variably shaped).

The electron beam B with a second aperture image, which has passed through the variable shaped opening 34 of the second shaping aperture 207, is focused by the objective lens 208, deflected by the main deflector 209 and the sub-deflector 210, and is emitted to the substrate 240 placed on the XY stage 211 which moves continuously.

FIG. 2 is a schematic view for explaining beam shaping by the first shaping aperture 204 and the second shaping aperture 207. In the first shaping aperture 204, the opening 32 for shaping the electron beam B is formed.

In addition, in the second shaping aperture 207, the variable shaped opening 34 is formed for shaping the electron beam B, which has passed through the opening 32 of the first shaping aperture 204, into a desired shape. The shape of a beam, which has passed through both the opening 32 of the first shaping aperture 204 and the variable shaped opening 34 of the second shaping aperture 207, is irradiated in the writing area of the substrate 240 mounted on the XY stage 211 which moves continuously.

As illustrated in FIG. 1, the controller 100 has a control computer 110, a control circuit 120, storage units 130, 132, a detection circuit 140, and an atmospheric pressure sensor 150. The atmospheric pressure sensor 150 measures the atmospheric pressure at the location where the writing apparatus (writing unit 200) is installed. Writing data used as layout data is inputted from the outside to the storage unit 130 which stores the writing data. The storage unit 132 stores data of coefficients (correction coefficients) of a calculation formula for calculating a correction amount of the beam emission position according to the atmospheric pressure. The storage unit 132 may store a calculation formula instead of the correction coefficients.

The control computer 110 includes a shot data generator 111, a correction amount calculator 112, a correction residual calculator 113, a determining unit 114, and an updater 115. Each component of the control computer 110 may be comprised of hardware such as an electric circuit or comprised of software. When the component is comprised of software, a program which implements at least part of the function of the control computer 110 may be stored in a recording medium, and may be read and executed by a computer including an electric circuit. The recording medium is not limited to a removable magnetic disk or an optical disc, and may be a fixed type recording medium such as a hard disk drive or a memory.

The shot data generator 111 reads writing data from the storage unit 130, and performs data conversion processing in multiple stages to generate shot data. The shot data includes information such as a shot shape, a shot size, and a shot position.

The correction amount calculator 112 calculates a variation amount (correction amount) of the beam emission position due to the effect of atmospheric pressure from a calculation formula using the value of atmospheric pressure obtained from the atmospheric pressure sensor 150 and the correction coefficients stored in the storage unit 132.

The control circuit 120 controls a deflection amount of the blanker 203, the deflector 206, the main deflector 209, and the sub-deflector 210 using the generated shot data, and performs writing processing. The control circuit 120 adds the correction amount calculated by the correction amount calculator 112 to the shot position included in the shot data, and corrects the shot position. The control circuit 120 controls the deflection amount of the main deflector 209 and the sub-deflector 210 based on the corrected shot position.

The column 220 of the writing apparatus has a configuration in which cylindrical blocks are stacked in multiple stages. When the state of a joint portion of each block changes with the atmospheric pressure, and the same correction coefficients are continued to be used, the variation in the beam emission position cannot be corrected, and a correction residual may occur.

Thus, in the present embodiment, the amount of deviation (correction residual) of the beam emission position is regularly measured during writing processing, and correlation between change in the correction residual and change in the atmospheric pressure is checked. When the correlation coefficient (the absolute value of the correlation coefficient) is greater than or equal to a predetermined threshold, the correction coefficients in the storage unit 132 are updated. Hereafter, the correction amount calculator 112 calculates the correction amount of the shot position using the updated correction coefficients.

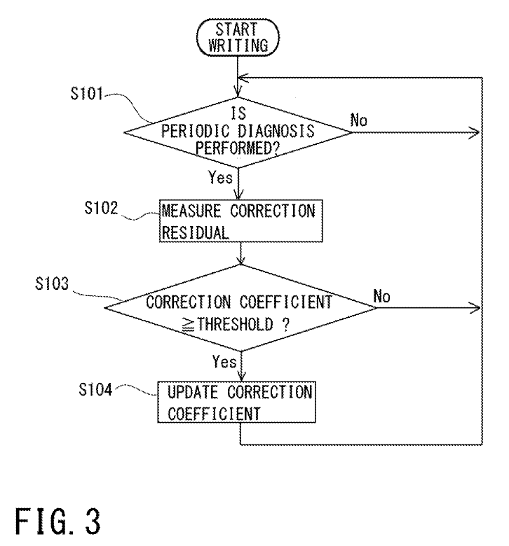

A method of updating a correction coefficient will be described with reference to the flowchart illustrated in FIG. 3. At a predetermined timing such as periodic diagnosis (Yes in step S101), a correction residual is measured (step S102). First, the XY stage 211 is moved so that the mark M is aligned to the center position of the objective lens 208. The cross shape of the mark M is then scanned by the electron beam B. A reflection electron from the mark M is detected by the detector 250, amplified by the detection circuit 140, and converted to digital data, then measurement data is outputted to the control computer 110. The correction residual calculator 113 calculates a correction residual based on the mark position measured by scanning the mark M, and the deflection position set to the deflector using the current correction coefficients. The calculated correction residual is stored in a storage unit which is not illustrated. The atmospheric pressure measured by the atmospheric pressure sensor 150 is also stored in the storage unit.

The determining unit 114 calculates a correlation coefficient between change in the correction residual and change in the atmospheric pressure in a certain period, and determines whether or not the absolute value of the correlation coefficient is greater than or equal to a predetermined threshold (step S103). When the correlation coefficient is greater than or equal to a predetermined threshold (Yes in step S103), the updater 115 updates the correction coefficient in the storage unit 132 (step S104). The updater 115 updates the correction coefficient so that the correction residual is reduced. When the correlation coefficient is less than a predetermined threshold (No in step S103), the current correction coefficients are maintained.

In this manner, according to the present embodiment, when there is a correlation between change in the correction residual and change in the atmospheric pressure, the correction coefficient is updated (changed), and thus it is possible to correct a deviation of the beam emission position due to a change in the atmospheric pressure with high accuracy.

As a result of intensive study by the inventor to achieve correction of deviation of the beam emission position due to the atmospheric pressure, the following findings have been obtained: deviation of the beam emission position due to change in the atmospheric pressure behaves differently between at the time of increase in the atmospheric pressure and at the time of decrease in the atmospheric pressure. Therefore, the storage unit 132 may store a first correction coefficient for the time of increase in the atmospheric pressure, and a second correction coefficient for the time of decrease in the atmospheric pressure, and the correction coefficient may be selectively used according to whether the atmospheric pressure is increasing or decreasing.

For example, when the atmospheric pressure is increasing, the correction amount calculator 112 calculates a correction amount using the first correction coefficient. On the other hand, when the atmospheric pressure is decreasing, the correction amount calculator 112 calculates a correction amount using the second correction coefficient.

Instead of the first correction coefficient and the second correction coefficient, a first calculation formula for calculating a correction amount at the time of increase in the atmospheric pressure, and a second calculation formula for calculating a correction amount at the time of decrease in the atmospheric pressure may be stored in the storage unit 132.

When there is a correlation between change in the correction residual and change in the atmospheric pressure, at least one of the first correction coefficient and the second correction coefficient may be updated using the same method as described in the embodiment. When the correlation coefficient between change in the correction residual and change in the atmospheric pressure is less than a predetermined threshold, and there is no correlation therebetween, the values of the first correction coefficient and the second correction coefficient are maintained.

In the embodiment, a configuration has been described in which an electron beam is used as an example of a charged particle beam. However, the charged particle beam is not limited to an electron beam, and may be a beam using a charged particle such as an ion beam.

In the embodiment, an example of a writing apparatus using a single beam has been described. However, the present disclosure is also applicable to a writing apparatus using a multi-beam.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam writing apparatus comprising:
a shot data generator generating shot data from writing data, the shot data including a position and a beam emission time for each shot;
a storage storing coefficients of a calculation formula for calculating a correction amount of a beam emission position according to an atmospheric pressure;
an atmospheric pressure sensor measuring the atmospheric pressure;
a correction amount calculator calculating a correction amount of the beam emission position from a measured value of the atmospheric pressure sensor and the calculation formula using the coefficients;
a writer writing a pattern on a substrate using a charged particle beam with the beam emission position adjusted based on the shot data and the correction amount;
a detector scanning a mark, provided on a stage on which the substrate is placed, with the charged particle beam, and detecting a reflection electron reflected from the mark;
a correction residual calculator calculating a correction residual for the emission position of the charged particle beam using a result of detection by the detector; and
an updater updating the coefficients, when there is correlation between change in the correction residual and change in the atmospheric pressure.

2. The apparatus according to claim 1,
wherein when an absolute value of a correlation coefficient between the change in the correction residual and the change in the atmospheric pressure is less than a predetermined value, values of the coefficients stored in the storage are maintained.

3. The apparatus according to claim 1,
wherein the writer includes a column provided with a discharger that discharges the charged particle beam, and a writing chamber provided with the stage, and
the column includes stacked cylindrical blocks.

4. A charged particle beam writing apparatus comprising:
a shot data generator generating shot data from writing data, the shot data including a position and a beam emission time for each shot;
a storage storing coefficients of a calculation formula for calculating a correction amount of a beam emission position according to an atmospheric pressure;
an atmospheric pressure sensor measuring the atmospheric pressure;
a correction amount calculator calculating a correction amount of the beam emission position from a measured value of the atmospheric pressure sensor and the calculation formula using the coefficients; and
a writer writing a pattern on a substrate using a charged particle beam with the beam emission position adjusted based on the shot data and the correction amount,
wherein the storage stores a first coefficient and a second coefficient different from the first coefficient, and
the correction amount calculator calculates a correction amount from the calculation formula using the first coefficient at a time of atmospheric pressure increase, and calculates a correction amount from the calculation formula using the second coefficient at a time of atmospheric pressure decrease.

5. The apparatus according to claim 3, further comprising:
a detector scanning a mark, provided on a stage on which the substrate is placed, with the charged particle beam, and detecting a reflection electron reflected from the mark;
a correction residual calculator calculating a correction residual for the emission position of the charged particle beam using a result of detection by the detector; and
an updater updating at least one of the first coefficient and the second coefficient, when there is correlation change in the correction residual and change in the atmospheric pressure.

6. The apparatus according to claim 4,
wherein the writer includes a column provided with a discharger discharging the charged particle beam, and a writing chamber provided with a stage on which the substrate is placed, and
the column includes cylindrical blocks stacked in a plurality of stages.

7. A charged particle beam writing method comprising:
generating shot data from writing data, the shot data including a position and beam emission time for each shot;
measuring an atmospheric pressure by an atmospheric pressure sensor;
calculating a correction amount of a beam emission position from a measured value of the atmospheric pressure and a predetermined calculation formula;
writing a pattern on a substrate using a charged particle beam with the beam emission position adjusted based on the shot data and the correction amount;
scanning a mark, provided on a stage on which the substrate is placed, with the charged particle beam, and detecting a reflection electron reflected from the mark;
calculating a correction residual for the emission position of the charged particle beam using a result of detection of the reflection electron; and
updating coefficients of the calculation formula when there is correlation between change in the correction residual and change in the atmospheric pressure.

8. The method according to claim 7,
wherein the correction amount is calculated using different calculation formulas at a time of atmospheric pressure increase and at a time of atmospheric pressure decrease.
